(19) United States
(12) Patent Application Publication
(10) Pub. No.: US 2010/0209702 A1
(43) Pub. Date: Aug. 19, 2010

(54) COMPOSITE LAYER AND FABRICATION METHOD THEREOF

(75) Inventors: Feng-Yu Tsai, Taipei City (TW); Chih-Yu Chang, Taipei City (TW); Yun-Jun Lee, Taipei City (TW)

Correspondence Address: QUINTERO LAW OFFICE, PC, 615 Hampton Dr, Suite A202, Venice, CA, 90291, US

(73) Assignee: NATIONAL TAIWAN UNIVERSITY, Taipei (TW)

(21) Appl. No.: 12/431,565

(22) Filed: Apr. 28, 2009

(30) Foreign Application Priority Data
Feb. 16, 2009 (TW) TW98104804

(51) Int. Cl. B32B 15/04; C23C 16/44

(52) U.S. Cl. 428/336; 427/255.28; 428/701

(57) ABSTRACT

The invention provides a method for forming a composite membrane, including: (a) loading a substrate into a chamber; (b) performing a first cycle step in the chamber to form a single aluminum oxide (Al₂O₃) layer; and (c) performing a second cycle step in the chamber to form a single hafnium oxide (HfO₂) layer. The steps include: (1) introducing an Al element containing a first reactant into the chamber; (2) removing the first reactant from the chamber; (3) introducing an O element containing a second reactant into the chamber; (4) removing the second reactant from the chamber; (5) introducing an Hf element containing a third reactant into the chamber; and (6) removing the third reactant from the chamber. The first cycle step is composed of steps (1) to (4), and the second cycle step is composed of steps (3) to (6).

### CROSS REFERENCE TO RELATED APPLICATIONS

This Application claims priority of Taiwan Patent Application No. 98104804, filed on Feb. 16, 2009, the entirety of which is incorporated by reference herein.

### BACKGROUND OF THE INVENTION

1. Field of the Invention

The present invention relates to atomic layer deposition process techniques, particularly to a method for forming a composite layer having various inorganic oxide single layers by the atomic layer deposition process technique.

2. Description of the Related Art

There are three types of conventional methods for forming gas barrier membranes: (1) sputtering methods, except for the atomic layer deposition process (ALD) method, for inorganic gas barrier membranes; (2) methods that alternately arrange organic layers and inorganic layers for multi-layered gas barrier membranes; and (3) ALD methods for inorganic gas barrier membranes. The disadvantages of the conventional methods are described below.

For the sputtering methods disclosed in U.S. Pat. No. 6,198,220 B1 or U.S. Pat. No. 5,771,562, except for the atomic layer deposition process (ALD) method, gas barrier efficiency is insufficient for organic photoelectric device gas-barrier layers fabricated thereby (oxygen transmission rate below 1*10⁻³-1*10⁻⁵ mol/m² day and water transmission rate below 1*10⁻⁶ mol/m² day). The insufficiency is due to the plurality of cavities formed therein, during fabrication.

For the methods that alternately arrange organic layers and inorganic layers disclosed in U.S. Pat. No. 5,952,778, U.S. Pat. No. 6,522,067 B1, U.S. Pat. No. 6,573,652 B1, U.S. Pat. No. 6,614,057 B2, U.S. Pat. No. 6,624,568 B2, U.S. Pat. No. 6,198,217 B2, U.S. Pat. No. 5,811,177, U.S. Pat. No. 6,911,667 B2, U.S. Pat. No. 7,317,280 B2, U.S. Pat. No. 6,146,225, and U.S. Pat. No. 6,949,825 B2, gas barrier efficiency is sufficient for organic photoelectric device gas-barrier layers fabricated thereby. However, the method is complex, time-consuming and not feasible.

For the ALD methods disclosed in US 2002/0003403 A1, US 2006/0246811 A1, US 2006/0250084 A1, and US 2007/0114925 A1, gas barrier efficiency of is sufficient for organic photoelectric device with organic/inorganic multiple-layer gas-barrier membrane fabricated thereby. However, this technique has disadvantages of complicated and time-consuming process for forming alternate organic/inorganic films and extremely low practicality.

### BRIEF SUMMARY OF INVENTION

A detailed description is given in the following embodiments with reference to the accompanying drawings.

The invention provides a method for forming a composite membrane, comprising: (a) loading a substrate into a chamber; (b) performing a first cycle step in the chamber to form a single aluminum oxide (Al₂O₃) layer; and (c) performing a second cycle step in the chamber to form a single hafnium oxide (HfO₂) layer. The steps comprise: (1) introducing an Al element containing a first reactant into the chamber; (2) removing the first reactant from the chamber; (3) introducing an O element containing a second reactant into the chamber; (4) removing the second reactant from the chamber; (5) introducing an Hf element containing a third reactant into the chamber; and (6) removing the third reactant from the chamber. The first cycle step is composed of steps (1) to (4), and the second cycle step is composed of steps (3) to (6).

The invention also provides a composite membrane formed on a substrate by an atomic layer deposition process, comprising: a plurality of single aluminum oxide (Al₂O₃) layers; and a plurality of single hafnium oxide (HfO₂) layers, wherein the single aluminum oxide layers and single hafnium oxide layers are alternately arranged.

### BRIEF DESCRIPTION OF DRAWINGS

The present invention can be more fully understood by reading the subsequent detailed description and examples with references made to the accompanying drawings, wherein:

FIG. 1 is a flow chart according to examples of the present invention.

FIGS. 2A to 2B are cross-sectional views of the first example of the present invention at various fabrication stages.

FIG. 2C shows variations of the helium transmission rate (HeTR) under air, during packing of the membrane of the first example of the present invention.

FIGS. 3A to 3B are cross-sectional views of the second example of the present invention at various fabrication stages.

FIG. 3C illustrates decay of photoelectric conversion efficiency of the photoelectric device of the second example of the present invention.

### DETAILED DESCRIPTION OF INVENTION

The present invention provides a method for forming an inorganic oxide composite membrane by and atomic layer deposition (ALD) process. In the composite membrane, each single layer is ultra-thin, having an atomic scale with minimal defects. Therefore, the ultra-thin composite membrane is suitable to be applied as a gas barrier membrane.

The present invention utilizes a single atomic layer deposition process.

The composite membrane of the present invention may be a multi-layered membrane composed of two or various kinds of alternately stacked inorganic oxide layers. In a preferred embodiment, the composite membrane is composed of an Al₂O₃ single layer and HfO₂ single layer alternately arranged.

The composite membrane of the present invention can be used for isolating gases (such as moisture or oxygen) in applications including packaging membranes for displays solar cells, and integrated circuits (IC), and particular, packaging membranes for soft displays, soft solar cells, and soft integrated circuits.

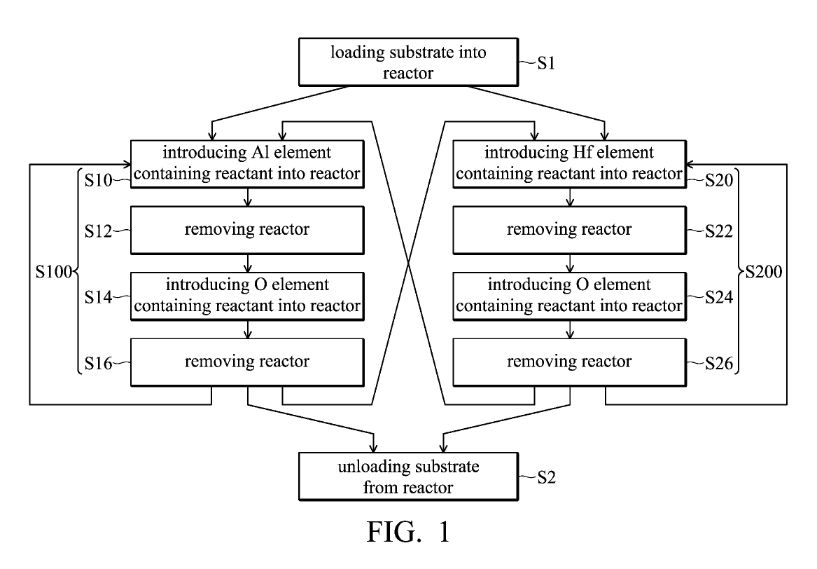

FIG. 1 is a flow chart according to embodiments of the present invention. First, a substrate is loaded into a reactor (not shown) (step S1). Next, a cycle step S100 may be implemented for forming an aluminum oxide single layer, or a cycle step S200 may be implemented for forming a hafnium oxide single layer. The sequence of the aluminum oxide single layer forming step (S100) and the hafnium oxide single layer forming step (S200) is not limited and can be varied according to the desired composite membrane structure. Therefore, the cycle step S100 may be implemented for forming the aluminum oxide single layer before implementing the cycle step S200 for forming the hafnium oxide single layer. Alternatively, the cycle step S200 may be implemented for forming the hafnium oxide single layer before implementing the cycle step S100 for forming the aluminum oxide single layer. In the embodiments, the composite forming step is implemented at a temperature of 100° C. to 300° C.

The cycle step S100 for forming the aluminum oxide single layer is composed of steps S10, S12, S14, and S16. In the step S10, an Al element containing reactant is introduced into the reactor. In the embodiments, the Al element containing reactant includes, but is not limited to, precursors such as trimethylaluminium (TMA), dimethylaluminum isopropoxide, tert-butoxy dimethylaluminum, dimethylaluminum isopropoxide, or sec-butoxy dimethylaluminum. The reactant, with a flow rate of 5 sccm to 100 sccm, is introduced into the reactor for 0.02 seconds to 1 second. The pressure of the reactor is controlled to be 0.1 Torr to 10 Torrs. Next, the Al element containing reactant is removed from the reactor (S12). The removal step S12 may be implemented by a pumping vacuum or introducing an inert gas into the reactor. The amount of time for the removal step is 1 second to 100 seconds. In one example, wherein pumping for vacuum is implemented, pumping is continuously performed with a vacuum pump and with no gas introduced into the reactor. In the step S14, an O element containing reactant is introduced into the reactor. The O element containing reactant includes, but is not limited to, water, oxygen, or ozone. The reactant, with a flow rate of 5 sccm to 100 sccm, is introduced into the reactor for 0.02 seconds to 1 second. The pressure of the reactor is controlled to be 0.1 Torr to 10 Torrs. Next, the O element containing reactant is removed from the reactor (S16). Similarly with the step S12, the removal step S16 may be implemented by a pumping vacuum or introducing an inert gas into the reactor. The amount of time for the removal step is 1 second to 100 seconds.

It should be understood that the step sequence in the cycle step S100 for forming the aluminum oxide single layer is not limited to be steps S10, S12, S14, and S16 as shown in FIG. 1, and can be steps S14, S16, S10, and S12. The thickness of the aluminum oxide single layer is increased by repeating the cycle step S100. In the embodiments, the thickness of the aluminum oxide single layer is 1 Å to 10 Å. Referring to FIG. 1, the cycle step S200 for forming the hafnium oxide single layer is composed of steps S20, S22, S24, and S26. In the step S20, an Hf element containing reactant is introduced into the reactor. In the embodiments, the Hf element containing reactant includes, but is not limited to, a precursor, such as tetrakis(dimethylamido)hafnium, hafnium 3-methyl-3-pentoxide, or hafnium chloride. The reactant, with a flow rate of 5 sccm to 100 sccm, is introduced into the reactor for 0.02 seconds to 5 seconds. The pressure of the reactor is controlled to be 0.1 Torr to 10 Torrs. Next, similarly with the removal step S12, the Hf element containing reactant is removed from the reactor (S22). The amount of time for the removal step is 1 second to 100 seconds.

In the step S24, an O element containing reactant is introduced into the reactor. The O element containing reactant includes, but is not limited to, water, oxygen, or ozone. The reactant, with a flow rate of 5 sccm to 100 sccm, is introduced into the reactor for 0.02 seconds to 1 second. The pressure of the reactor is controlled to be 0.1 Torr to 10 Torrs. Next, similarly with the removal step S12, the O element containing reactant is removed from the reactor (S26).

It should be understood that the step sequence in the cycle step S200 for forming the hafnium oxide single layer is not limited to be steps S20, S22, S24, and S26 as shown in FIG. 1, and can be steps S24, S26, S20, and S22. The thickness of the hafnium oxide single layer is increased by repeating the cycle step 2100. In the embodiments, the thickness of the hafnium oxide single layer is 1 Å to 10 Å. Referring to FIG. 1, the composite membrane composed of alternate aluminum oxide single layers and hafnium oxide single layers may be formed on the substrate by alternately implementing the aluminum oxide single layer forming step and the hafnium oxide single layer forming step. The total thickness of the composite membrane is preferably, but is not limited to, 10 nm to 30 nm. Next, the substrate is unloaded from the reactor (step S2).

The following description is of the best-contemplated mode of carrying out the invention. This description is made for the purpose of illustrating the general principles of the invention and should not be taken in a limiting sense. The scope of the invention is best determined by reference to the appended claims.

### EXAMPLE 1

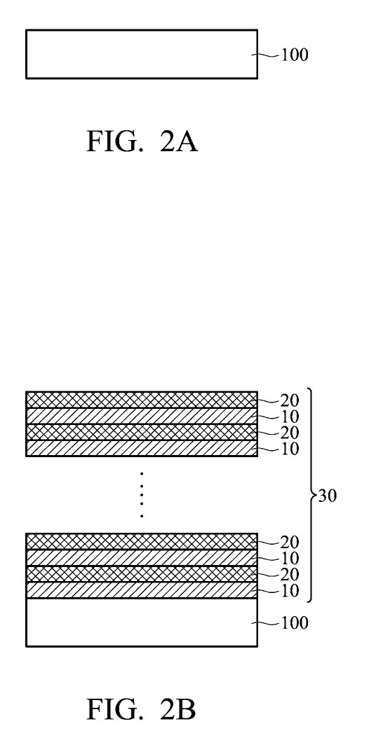

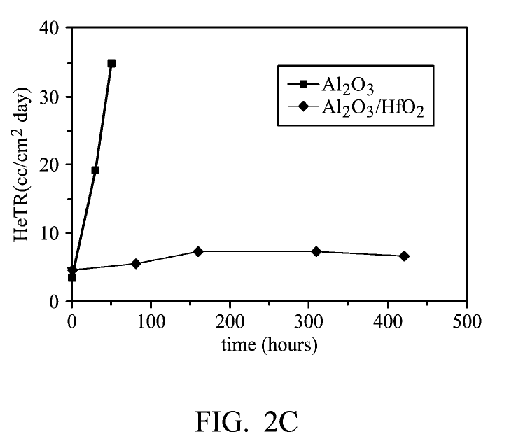

The polyimide substrate 100 as shown in FIG. 2A was loaded into a reactor. The reactor was heated to a temperature of 140° C. The trimethylaluminum, with a flow rate of about 20 sccm, was introduced into the reactor for about 0.03 seconds, and the pressure of the reactor was controlled at about 0.1 Torr. After the pumping vacuum was operated for about 5 seconds, water of about 20 sccm, was introduced into the reactor for about 0.02 seconds, and the pressure of the reactor was controlled at about 0.1 Torr. Then, the reactor was pumped vacuumed for about 5 seconds, to form the Al2O3 layer 10. Next, tetrakis(dimethylamido)hafnium, with a flow rate of 20 sccm, was introduced into the reactor for about 0.4 seconds, and the pressure of the reactor was controlled at about 0.1 Torr. After the pumping vacuum was operated for about 5 seconds, water of about 20 sccm, was introduced into the reactor for about 0.02 seconds, and the pressure of the reactor was controlled at about 0.1 Torr. Then, the reactor was pumped vacuumed for about 5 seconds, to form the HfO₂ layer 20. The cycle steps for forming the Al₂O₃ layer 10 and HfO₂ layer 20 were alternately implemented so as to form the composite membrane 30 covering the polyimide substrate 100 as shown in FIG. 2B. The composite membrane 30 was composed of 50 alternating Al₂O₃ layers 10 and HfO₂ layers 20. The thickness of each of the Al₂O₃ layers 10 was 2 Å, the thickness of each of the HfO₂ layers 20 was 3 Å, and the total thickness of the composite membrane 30 was 25 nm. FIG. 2C shows variations of the helium transmission rate (HeTR) under air, during packing of the membrane of Example 1 (“Al₂O₃/HfO₂”). Referring to FIG. 2C, the helium transmission rate of the single Al₂O₃ layer rapidly increased (due to hydrolysis reaction between Al₂O₃ and moisture in the air) during packing of the membrane, showing that gas barrier effect rapidly decreased. On the contrary, the gas barrier composite membrane had low helium transmission rate maintaining for a long time, showing its high gas barrier and stability characteristics.

### EXAMPLE 2

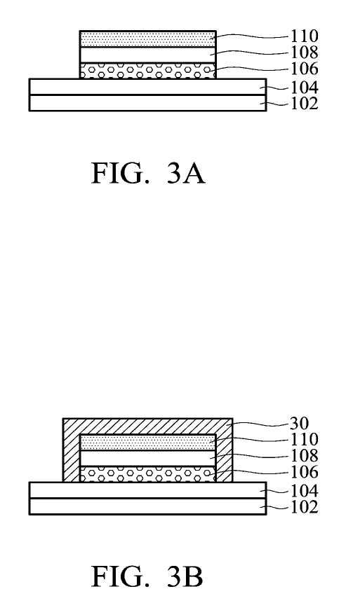

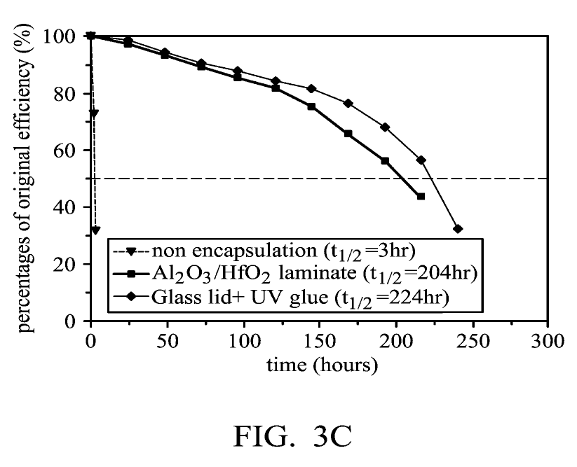

First, the organic solar cell structure, as shown in FIG. 3, comprising the ITO film 104, was formed on the glass substrate 102. Next, a 50 nm thick film 6 was disposed on the ITO film 104 by spin-coating a PEDOT:PSS water solution. Following, a 110 nm thick film 108 was disposed on the PEDOT:PSS film 106 by spin-coating a P3HT:PCBM mixture solution (with the chlorobenzene solvent, and mixing weight ratio of 1:08). Finally, a 250 nm thick Al film (used as the cathode) was disposed on the P3HT:PCBM film 108.

A composite membrane 30 composed of 50 alternating Al₂O₃ layers and HfO₂ layers, covering the solar cell as shown in FIG. 3B, was formed by the same method as Example 1. Similar with the composite membrane of Example 1, for the packing membrane 30, the thickness of each of the Al₂O₃ layers 10 was 2 Å, the thickness of each of the HfO₂ layers 20 was 3 Å, and the total thickness of the packaging membrane 30 was 25 nm.

A non-encapsulated solar cell device packaged by the conventional packing method (Comparative Example—glass lid attachment by UV curable resin), and an encapsulated solar cell device packaged by the composite laminate of Example 1, were tested for stability. For the stability tests, environment temperature was 29° C. and relative humidity (RH) was 60% for the solar cell devices. Current-voltage characteristics with illumination of AM 1.5 at 24-hour intervals were measured to observe decay of photoelectric conversion efficiency over time. As shown in FIG. 3C, the original efficiency percentages, represented by the vertical axis, were equal to the photoelectric conversion efficiency measured at the time larger than 0 divided by the photoelectric conversion efficiency measured at the time equal to 0. Accordingly, the non-encapsulated solar cell device (“non encapsulation”) showed rapid decay over time. The test result of the solar cell packaged with the ALD composite multiple laminate of this example (referring to the label of “Al₂O₃/HfO₂ laminate”) was similar to the solar cell packaged by the conventional method (referring to the label of “Glass lid+UV glue”), having excellent stability characteristic for maintaining stability for long time.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a composite membrane, comprising:
(a) loading a substrate into a chamber;
(b) performing a first cycle step in the chamber to form a single aluminum oxide (Al₂O₃) layer; and
(c) performing a second cycle step in the chamber to form a single hafnium oxide (HfO₂) layer,
wherein the first cycle step is composed of steps (1) to (4), and the second cycle step is composed of steps (3) to (6) of the following:
(1) introducing an Al element containing a first reactant into the chamber;
(2) removing the first reactant from the chamber;
(3) introducing an O element containing a second reactant into the chamber;
(4) removing the second reactant from the chamber;
(5) introducing an Hf element containing a third reactant into the chamber; and
(6) removing the third reactant from the chamber,

2. The method for forming the composite membrane as claimed in claim 1, wherein the first reactant includes trimethylaluminum, iso-propanol dimethylaluminum, tert-butoxy dimethylaluminum, or sec-butoxy dimethylaluminum.

3. The method for forming the composite membrane as claimed in claim 1, wherein the second reactant includes water, oxygen, or ozone.

4. The method for forming the composite membrane as claimed in claim 1, wherein the third reactant includes tetrakis(dimethylamido)hafnium.

5. The method for forming the composite membrane as claimed in claim 1, wherein the first reactant is trimethylaluminum, the second reactant is water, and the third reactant is tetrakis(dimethylamido)hafnium.

6. The method for forming the composite membrane as claimed in claim 1, wherein the step (b) further comprises repeating the first cycle step to increase the thickness of the single aluminum oxide layer.

7. The method for forming the composite membrane as claimed in claim 1, wherein the step (c) further comprises repeating the second cycle step to increase the thickness of the single hafnium oxide layer.

8. The method for forming the composite membrane as claimed in claim 1, wherein the thickness of the single aluminum oxide layer or single hafnium oxide layer is 1 Å to 10 Å.

9. The method for forming the composite membrane as claimed in claim 1, wherein the thickness of the composite membrane is 10 nm to 30 nm.

10. The method for forming the composite membrane as claimed in claim 1, wherein the composite membrane is used for a gas-barrier packaging membrane.

11. The method for forming the composite membrane as claimed in claim 1, wherein the substrate has an electric device disposed thereon, and the composite membrane covers the electric device.

12. The method for forming the composite membrane as claimed in claim 11, wherein the electric device includes an organic photoelectric device.

13. The method for forming the composite membrane as claimed in claim 12, wherein the organic photoelectric device includes a light emitting diode display, solar cell, or thin-film transistor.

14. The method for forming the composite membrane as claimed in claim 1, wherein each of the steps (2), (4), and (6) is performed by vacuuming or introducing an inert gas.

15. The method for forming the composite membrane as claimed in claim 14, wherein the time of the vacuuming or introducing an inert gas is 1 second to 100 seconds.

16. The method for forming the composite membrane as claimed in claim 1, wherein the pressure of the chamber in each of the steps (1), (3), and (5) is 0.1 Torr to 10 Torr.

17. The method for forming the composite membrane as claimed in claim 1, wherein the amount of time for introducing the first reactant in the step (1) is 0.02 seconds to 1 second, and the flow rate thereof is 5 sccm to 100 sccm.

18. The method for forming the composite membrane as claimed in claim 1, wherein the amount of time for introducing the second reactant in the step (3) is 0.02 seconds to 1 second, and the flow rate thereof is 5 sccm to 100 sccm.

19. The method for forming the composite membrane as claimed in claim 1, wherein the amount of time for introducing the third reactant in the step (5) is 0.02 seconds to 5 seconds, and the flow rate thereof is 5 sccm to 100 sccm.

20. The method for forming the composite membrane as claimed in claim 1, wherein the temperature of the chamber is 100° C. to 300° C.

21. A composite membrane formed on a substrate by an atomic layer deposition process, comprising:
a plurality of single aluminum oxide (Al₂O₃) layers; and
a plurality of single hafnium oxide (HfO₂) layers,
wherein the single aluminum oxide layers and single hafnium oxide layers are alternately arranged.

22. The composite membrane as claimed in claim 21, wherein the thickness of each of the single aluminum oxide layers or single hafnium oxide layers is 1 Å to 10 Å.

23. The composite membrane as claimed in claim 21, wherein the total thickness of the composite membrane is 10 nm to 30 nm.

24. The composite membrane as claimed in claim 21, wherein the composite membrane is used for a gas-barrier packaging membrane.

25. The composite membrane as claimed in claim 21, wherein the substrate has an electric device disposed thereon, and the composite membrane covers the electric device.

26. The composite membrane as claimed in claim 25, wherein the electric device includes an organic photoelectric device.

27. The composite membrane as claimed in claim 26, wherein the organic photoelectric device includes a light emitting diode display, solar cell, or thin-film transistor.
